(19) United States
(12) Patent Application Publication
(10) Pub. No.: US 2026/0107609 A1
(43) Pub. Date: Apr. 16, 2026

(54) SELECTIVE TRANSFER OF MICRO-LEDS

(71) Applicant: SmartKem Limited, Manchester (GB)

(72) Inventor: Simon OGIER, Manchester (GB)

(73) Assignee: SmartKem Limited, Manchester (GB)

(21) Appl. No.: 19/116,015

(22) PCT Filed: Sep. 25, 2023
(86) PCT No.: PCT/GB2023/052466

§ 371 Date: Mar. 27, 2025

(30) Foreign Application Priority Data
Sep. 27, 2022 (GB) 2214088.3

(51) Int. Cl. H10H 29/03; G01R 31/26; H10H 29/01; H10H 29/49; H10H 29/80

(52) U.S. Cl. CPC H10H 29/03; H10H 29/012; H10H 29/49; H10H 29/942; G01R 31/2601

(57) ABSTRACT

A method of fabricating a micro-LED display (300), the method comprising: providing (102) a micro-LED wafer (302) comprising an array of LEDs (304) deposited on a growth substrate (306); depositing (110) an adhesion layer (308) so as to cover the micro-LED wafer (302) while leaving one or more selected LEDs exposed; depositing (112) a backplane (310) on the adhesion layer (308), such that the backplane (310) is aligned with and operatively connected to the exposed one or more LEDs; and removing (114) the deposited backplane (310) and connected one or more LEDs to a display substrate (312).

### FIELD OF THE INVENTION

The present invention relates to method for selective transfer of micro-LEDs for a flat-panel display, more specifically a monolithic display.

### BACKGROUND

Micro-LED displays are an emerging flat-panel display technology, which use an array of microscopic LEDs for forming individual pixels. Micro-LED displays have many advantages over earlier liquid crystal displays (LCDs). For example, since the LEDs are only powered when a pixel is illuminated and can be completely turned off at other times, micro-LED displays are much more energy efficient, and have a better contrast ratio. Furthermore, micro-LED displays have a faster response time, thus making them more appropriate for augmented reality (AR) and virtual reality (VR) applications, where high pixel density and high frame rates are particularly useful.

Micro-LED displays are often made by transferring micro-LEDs from a source wafer onto a receiver substrate (the display backplane). This allows an RGB display to be made from individual red, green, and blue source micro-LED wafers. Often the pitch of the micro-LEDs on the source wafer is different to the backplane pixel pitch so techniques are required to transfer them in the correct place.

However, when individually moving pixels, it may take a considerable time using an expensive “pick-and-place” machine in order to produce a single display, which increases the cost of the displays. In an attempt to decrease the manufacturing time, it has also been considered to use an adhesive film to transport multiple pixels at a time onto the substrate.

However, the above processes have a number of challenges. In particular, the transfer process yield is not 100%, which results in backplanes with missing or misaligned pixels. This leads to further repair work in order to produce a fully working display, significantly increasing the cost of manufacturing these components. Since displays may have up to 24 million sub-pixels, success rates of at least 99.99999% are required. Currently, the best success rates may be about 99%. Such problems are particularly apparent when producing displays with very high resolution, pixel density and contrast ratios, such as displays for Augmented Reality (AR) or Virtual Reality (VR) devices, or smartwatches. Given that such devices may be increasingly in demand in future, there is a need for a better way to produce micro-LED displays.

One way to avoid transferring LEDs from the source wafer to the backplane is to process the backplane directly on top of the micro-LEDs on the source wafer, thereby producing a monolithic display. For example, a sapphire substrate may form the bottom layer of the monolithic display, with a micro-LED and a thin film transistor (TFT) deposited on top. Since TFTs are typically opaque to light, the area of each pixel needs to be shared between the TFT and the micro-LED, which reduces the current that can be driven from the display. Additionally, if the footprint of the TFT were reduced by using a higher mobility TFT (such as LTPS), the high temperature processes required to manufacture with LTPS would seriously damage the performance of the micro-LED.

A further problem with the monolithic display described above is that, all of the area of the source wafer is used up for each display. This is not necessary, since the micro-LEDs are bright enough even with only a small area of the source wafer emitting light, for example 5% of the area of the source wafer.

A further problem with the monolithic display described above is that, because the backplane is processed directly on top of the micro-LEDs on the source wafer, there is no way of repairing defective micro-LEDs on the source wafer.

Therefore, it is an object of the present invention to overcome one or more of the problems described above.

### SUMMARY OF INVENTION

According to a first aspect of the present invention there is provided a method of fabricating a micro-LED display, the method comprising: providing a micro-LED wafer comprising an array of LEDs deposited on a growth substrate; depositing an adhesion layer so as to cover the micro-LED wafer while leaving one or more selected LEDs exposed; depositing a backplane on the adhesion layer, such that the backplane is aligned with and operatively connected to the exposed one or more LEDs; and removing the deposited backplane and connected one or more LEDs to a display substrate.

In other words, one or more LEDs are selectively transferred from growth substrate to a display substrate. Therefore, the present invention departs from conventional fabrication methods of monolithic displays, in which the optoelectronic device and thin film transistor are grown on the same substrate (where the substrate may be later be removed). In monolithic displays, the components are grown or deposited on a particular layer, rather than those components being fabricated separately and joined together during a separate manufacturing stage. Instead, in the present invention the LED components are grown or deposited on a particular layer, other components are deposited on top of a selection of the LED components and then the selection of LED components and the connected components are removed to another substrate.

Advantageously, the first aspect of the present invention produces a monolithic display due to the fact that the backplane is deposited on the growth substrate, and thereby avoids the problems associated with transferring LEDs from a source wafer to a backplane. However, conventional monolithic displays do not make efficient use of the LEDs and growth substrate since the typical density of LEDs on the growth substrate is far greater than is required for a display, where the required brightness is met with only 5% of the area of each pixel emitting light. The present invention addresses this issue by only exposing a selection of the LEDs on the growth substrate for connection to the backplane, such that the LEDs can be selected at a suitable pitch to match the display. The one or more selected and utilised LEDs are then removed to a display substrate to build the display, leaving the remaining LEDs of the source wafer to be used again, either for another section of the same display or a new display.

As used herein, the terms “top”, “bottom”, “above”, and “below” refer to directions and relative positions as depicted in the figures. It will be appreciated that these terms do not require than any of the embodiments described herein may only be operated in a particular orientation. The term “top” indicates the growth direction, i.e. the direction of growth relative to a substrate (which the device may or may not have been removed from). In other words, the growth direction is perpendicular to a plane defined by the substrate, optoelectronic device, reflective layer, and/or the thin film transistor.

The phrase “micro-LED display” is used to refer to a display comprising an array of microscopic LEDs, where LEDs form the individual pixel elements. The LEDs themselves may have one or more dimensions on the micrometer scale but are not limited to this and may also have dimensions smaller or larger such as on the nanometer scale.

The phrase “backplane” is used to refer to circuitry for controlling the function of the LEDs. For example, the circuitry may comprise one or more transistors configured to control the supply of current to the LEDs. The backplane may include, for example, one or more thin film transistors and a capacitor. Alternatively, the backplane may comprise additional transistors, capacitors, and/or any further circuitry for individually addressing each of the integrated circuits. The backplane may comprise two transistors and a capacitor (e.g. a switch TFT and a drive TFT) to form a 2T-1C backplane arrangement. Processing of the backplane on the LEDs may refer to depositing TFTs and then etching and depositing connections to connect them to the LED.

The phrase “depositing” may refer to depositing performed using a chemical vapour deposition technique (CVD) such as plasma-enhanced chemical vapour deposition (PECVD) or metalorganic chemical vapour deposition (MOCVD), or an epitaxy technique such as metalorganic vapour-phase epitaxy (MOVPE), or molecular beam epitaxy (MBE). These techniques allow thin films (or “layers”) of material to be deposited on a substrate. Subsequently, portions of the layers may be selectively removed in a process known as patterning, which may be achieved by (dry) etching. In this way, it is possible to electrically isolate adjacent parts of layers from each other, and form channels for electrical pathways through the layers.

The micro-LED preferably comprises a number of semiconductor layers deposited sequentially and the thin film transistor comprises a plurality of layers deposited sequentially over the optoelectronic device.

In the method of fabricating a micro-LED display, the method step of depositing an adhesion layer may comprise depositing an adhesion layer to cover the micro-LED wafer; removing one or more sections of the adhesion layer to expose the one or more selected LEDs. By removing one or more specific sections of the adhesion layer to expose the one or more selected LEDs, after the adhesion layer has already been deposited, the one or more selected LEDs can be accurately aligned with the sections of the adhesion layer which are removed, in contrast to aligning an adhesion layer with sections already removed with the one or more selected LEDs.

The adhesion layer may comprise a photoresist. When the adhesion layer comprises a photoresist, the method of fabricating a micro-LED display may further comprise exposing the one or more sections of the adhesion layer to light to expose the one or more selected LEDs. In this way, the one or more sections of the adhesion layer may be more accurately and precisely removed to expose the one or more selected LEDs, as it is easier to control the expose of the one or more sections of the adhesion layer to light.

In the method of fabricating a micro-LED display, the method step of providing a micro-LED wafer may comprise depositing a sequence of semiconductor layers to form the array of LEDs on the growth substrate. In this way, a monolithic micro-LED wafer may be provided and thereby transferring LEDs from a source wafer to a backplane is avoided. The LEDs may comprise any morphology and materials to provide the required illumination. For example the LEDs may comprise III-V nitride materials, such as gallium nitride and/or indium gallium nitride. The LEDs may comprise one or more quantum wells and/or quantum dots.

In the method of fabricating a micro-LED display, prior to depositing the adhesion layer, the method may further comprise depositing a wiring pattern on the micro-LED wafter to connect the array of LEDs to a current source; applying a current to the wiring pattern to test the LEDs; and selecting one or more correctly functioning LEDs as the one or more selected LEDs to be connected to the backplane and removed to the display substrate. In this way, it is possible to wire up all of the LEDs prior to backplane processing and illuminate all of the pixels simultaneously to determine which ones are working and which are not. An image of the illuminated LEDS can then be used to determine which LEDs to avoid when building a display.

In the method of fabricating a micro-LED display, the method step of selecting one or more functioning LEDs may further comprise: capturing an image of the micro-LED wafer while the current is applied to the wiring pattern to illuminate the array of LEDs; processing the image to identify locations of correctly functioning LEDs; and selecting one or more correctly functioning LEDs as the one or more selected LEDs to be connected to the backplane and removed to the display substrate. In this way, it is possible to identify which LEDs are correctly functioning, so only the correctly functioning LEDs are used to fabricate the micro-LED display and banded to the backplane and the incorrectly functioning LEDs can be avoided.

In the method of fabricating a micro-LED display, the method may further comprise removing the deposited wiring pattern from the one or more selected LEDs so that the one or more selected LEDs are not attached to the rest of the array of LEDs. In this way, after testing of the LEDs, the deposited backplane and one or more selected LEDs can be easily removed from the to a display substrate, without connected wiring hindering the removal.

In the method of fabricating a micro-LED display, the method step of removing the exposed deposited circuitry may further comprise wet etching the exposed deposited circuitry. In this way, the exposed deposited circuitry may be removed in an efficient and low cost manner.

In the method of fabricating a micro-LED display, the method may further comprise removing the deposited adhesion layer from the backplane. In this way, no adhesion layer remains on the backplane, so that it can be removed and attached to a display substrate in the desired manner.

In the method of fabricating a micro-LED display, the method step of removing the deposited backplane and connected one or more LEDs to a display substrate may further comprise attaching the display substrate on the deposited backplane; freeing the one or more selected LEDs from the growth substrate of the micro-LED wafer; and lifting away the display substrate with the attached backplane and one or more connected LEDs. In this way, the deposited backplane and connected one or more LEDs are efficiently removed to a display substrate.

In the method of fabricating a micro-LED display, the method step of freeing the one or more selected LEDs from the growth substrate comprises ablating the one or more LEDs with a laser. Laser ablation allows for LED to removed from the growth substrate in a controlled manner without damaging the LED itself. In particular it allows for a very thin layer of material to be removed or converted to a low melting point metal (e.g. GaN converted to Ga metal) to free the LED, without the remaining LED absorbing significant energy.

In the method of fabricating a micro-LED display, the display substrate may comprise a laminate plastic substrate and/or a flexible substrate. In this way, a flexible micro-LED display or device may be fabricated.

In the method of fabricating a micro-LED display, the display substrate may comprise a polymer coated from solution and cured to form a thick polymer film.

In the method of fabricating a micro-LED display, the backplane may comprise one or more thin film transistors, TFTs. The method step of depositing the backplane on the adhesive layer may further comprise connecting the one or more TFTs to the exposed one or more LEDs.

In the method of fabricating a micro-LED display, the one or more selected LEDs may comprise a sub array of selected LEDs within the array of LEDs on the micro-LED wafer with the separation of the selected LEDs in the sub array corresponding to a required pixel separation of the micro-LED display. By having a sub array of selected LEDs with a required pixel separation of the micro-LED display, multiple LEDs can be removed to the display substrate at once, while having the correct separation when they are deposited on the display substrate. This reduces the number of separate transfers of LEDs which need to be made to the display substrate in order to fabricate a micro-LED display. More specifically, an array of LEDs can be selected that match the required pitch of the pixels of the display. Since the LEDs are grown in a much denser array than required for the pixels of the display, when exposing LEDs for transfer, a plurality of LEDs can be selected so as to provide one (or more than one) per pixel of the display.

In the method of fabricating a micro-LED display, after the method step of removing the deposited backplane and the one or more connected LEDs to a display substrate, and where the deposited backplane is defined as a first backplane, the method may further comprise depositing an adhesion layer so as to cover the micro-LED wafer while leaving one or more further LEDs exposed; depositing a second backplane such that the second backplane is aligned with and operatively connected to the exposed one or more further LEDs; and removing the deposited second backplane and connected one or more further LEDs to a display substrate. In this way, the overall cost of the fabricating the micro-LED display may be reduced, since the same micro-LED wafer can be used multiple times. This further reduces the number of micro-LED wafers which need to be produced, since each LED on the wafer may be transferred to a display substrate.

In the method of fabricating a micro-LED display, the deposited second backplane and connected one or more further LEDs may be removed to the same display substrate as the first backplane. In this way, the overall cost of the fabricating the micro-LED display may be reduced, since the same micro-LED wafer can be used multiple times.

In the method of fabricating a micro-LED display, the LEDs may comprise one or more of micro-LEDs, nano-LEDs, quantum dots. In particular the size of the LED may be selected depending on the type of display required, for example taking into account the size of the display, the size of the pixels and/or the brightness required.

In the method of fabricating a micro-LED display, the growth substrate may be a sapphire substrate. Sapphire provides appropriate lattice matching for growth of a number of different semiconductor materials to form the LEDs, most preferably the III-V Nitrides.

In the method of fabricating a micro-LED display, the method step of removing one or more sections of the adhesion layer to expose the one or more selected LEDs may further comprise using digital lithography to define the one or more selected LEDs which are exposed. Digital lithography allows for a user-specified or automatically generated pattern, of arbitrary shape, to be applied to the adhesion layer. In particular the method may comprise determining a selection of LEDs on the growth substrate that have the correct pitch for the micro-LED display and that are functioning correctly, creating a mask pattern corresponding to the positions of the selection of LEDs, using digital lithography to apply the mask pattern to expose the LEDs. By selecting specific LEDs, the use of digital lithography enables a random distribution of defective LEDs to be avoided.

According to another aspect of the present invention there is provided a micro-LED display comprising: a plurality of LEDs, each having a top surface and an opposing bottom surface; a backplane having a top surface and an opposing bottom surface, the backplane formed over the top surface of the LEDs, wherein the bottom surface of the backplane is deposited directly on and operatively connected to the LEDs; and a display substrate attached to the top surface of the backplane.

The present invention departs from conventional monolithic displays, in which the optoelectronic device and thin film transistor are grown on the same substrate (where the substrate may be later be removed). In monolithic displays, the components are grown or deposited on a particular layer, rather than those components being fabricated separately and joined together during a separate manufacturing stage. Instead, in the present invention the LED components are grown or deposited on a particular layer, other components are deposited on top of a section of the LED components and then the section of LED components and other components are removed to another substrate. Advantageously, this aspect of the present invention produces a monolithic display and thereby avoids transferring LEDs from a source wafer to a backplane.

In the micro-LED display the top surface of the LEDs may correspond to the growth direction and the bottom surface may be been removed from a growth substrate.

In the micro-LED display the display substrate may comprise a laminate plastic substrate applied to the top surface of the backplane. In this way, the micro-LED display or device may be flexible.

The micro-LED display may further comprise a reflective layer formed between a top surface of the one or more LEDs and the backplane, the reflective layer arranged to reflect light emitted by the LEDs such that reflected light is emitted from the micro-LED display in a direction corresponding to the bottom surface of the LEDs. The use of a reflective layer allows all, or a majority of light, to be emitted in one direction through one side of the micro-LED display. In this way, the reflective layer leads to a greater proportion of the light from the LEDs being directed in one direction, thereby increasing the efficiency of the micro-Led display.

According to another aspect of the present invention, there is provided a virtual reality or augmented reality headset comprising the above-set out micro-LED display.

According to another aspect of the present invention, there is provided a smartwatch comprising the above-set out micro-LED display.

According to another aspect of the present invention, there is provided an integrated circuit for testing LEDs for a micro-LED display. The integrated circuit comprising: a micro-LED wafer comprising an array of LEDs deposited on a growth substrate; and a wiring pattern deposited on the micro-LED wafer to connect each of the LEDs of the array of LEDs to a current source to test the LEDs prior to transfer to a micro-LED display. In this way, it is possible to wire up all of the LEDs prior to backplane processing and illuminate all of the pixels simultaneously to determine which ones are working and which are not. An image of the illuminated LEDS can then be used to determine which LEDs to avoid when building a display.

It will be understood by a skilled person that any apparatus feature described herein may be provided as a method feature, and vice versa. It will also be understood that particular combinations of the various features described and defined in any aspects described herein can be implemented and/or supplied and/or used independently.

Moreover, it will be understood that the present invention is described herein purely by way of example, and modifications of detail can be made within the scope of the invention.

### BRIEF DESCRIPTION OF DRAWINGS

One or more embodiments will now be described, purely by way of example, with reference to the accompanying figures, in which:

FIG. 1 shows a flow diagram setting out a method of fabricating a micro-LED display according to an embodiment.

FIG. 2 shows a flow diagram setting out a method of selecting correctly functioning LEDs as part of a method of fabricating a micro-LED display according to an embodiment.

FIGS. 3a to 3i shows schematic diagrams illustrating a method of fabricating a micro-LED display according to an embodiment.

FIG. 4a shows a schematic diagram of a micro-LED display.

FIG. 4b shows a schematic diagram of a display component formed form a plurality of pixels.

FIG. 4c shows a transistor array for a backplane of a display.

FIG. 4d shows an integrated circuit that may form part of the transistor array of FIG. 4c.

FIG. 5 shows a schematic diagram of a backplane utilised in a method of fabricating a micro-LED display according to an embodiment.

### DETAILED DESCRIPTION

In the following description and accompanying drawings, corresponding features may preferably be identified using corresponding reference numerals to avoid the need to describe said common features in detail for each and every embodiment.

For clarity and brevity, the terms “top”, “bottom”, “above”, and “below” refer to directions and relative positions as depicted in the figures. It will be appreciated that these terms do not require that any of the embodiments described herein may only be operated in a particular orientation. Furthermore, unless explicitly specified otherwise, terms such as “located”, “positioned”, “disposed” are merely intended to express relative position of two components or layers, and do not exclude other components from being located between said two components.

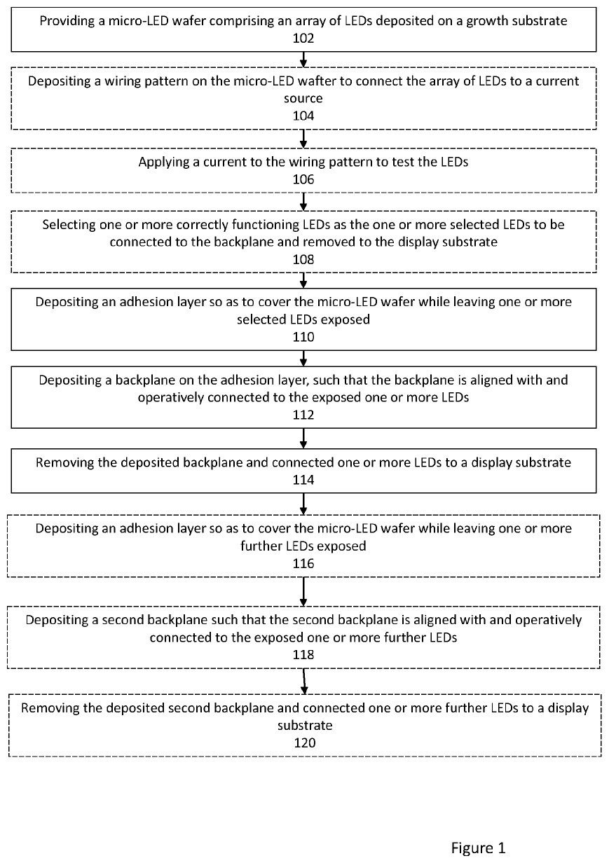

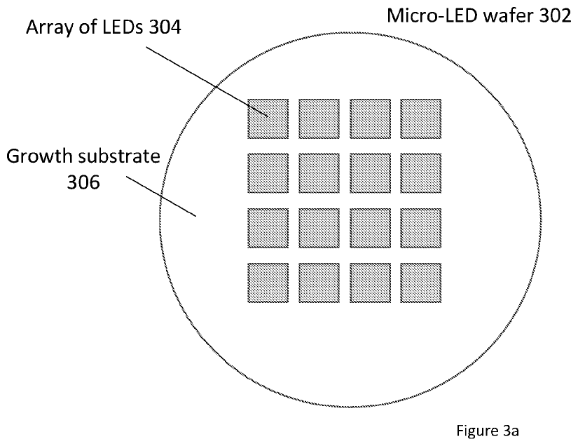

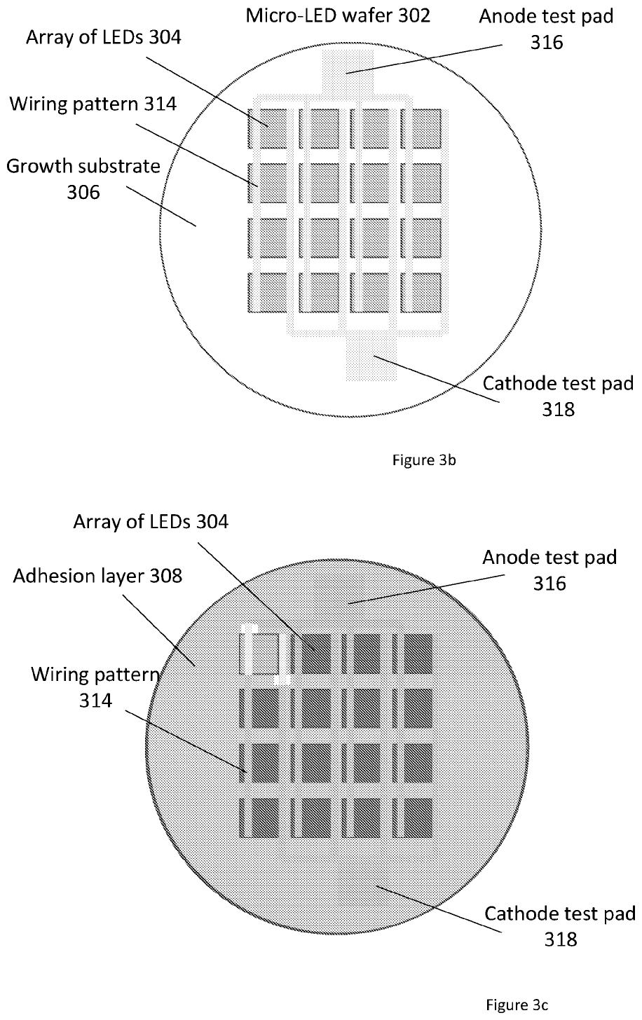

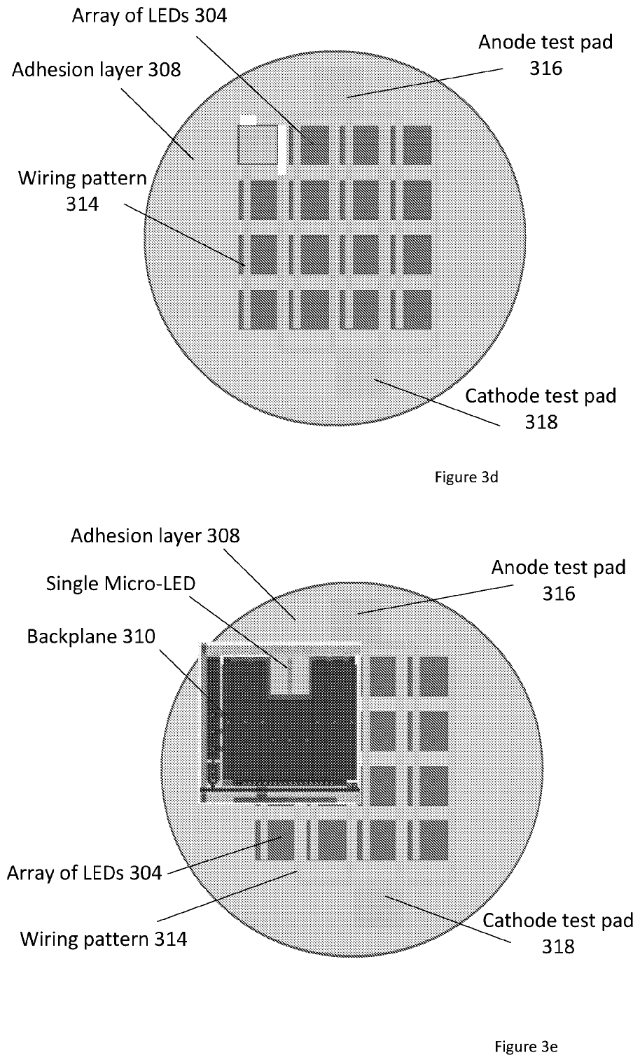

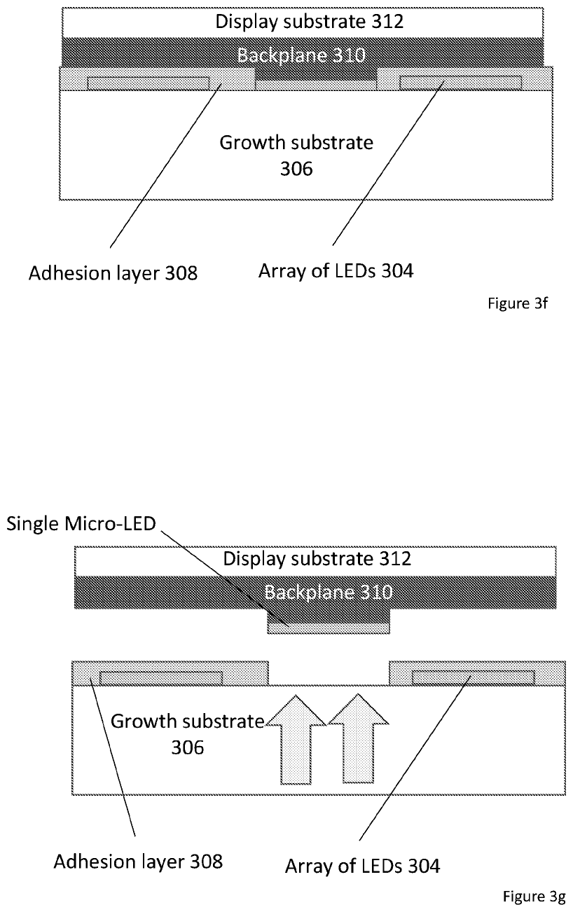

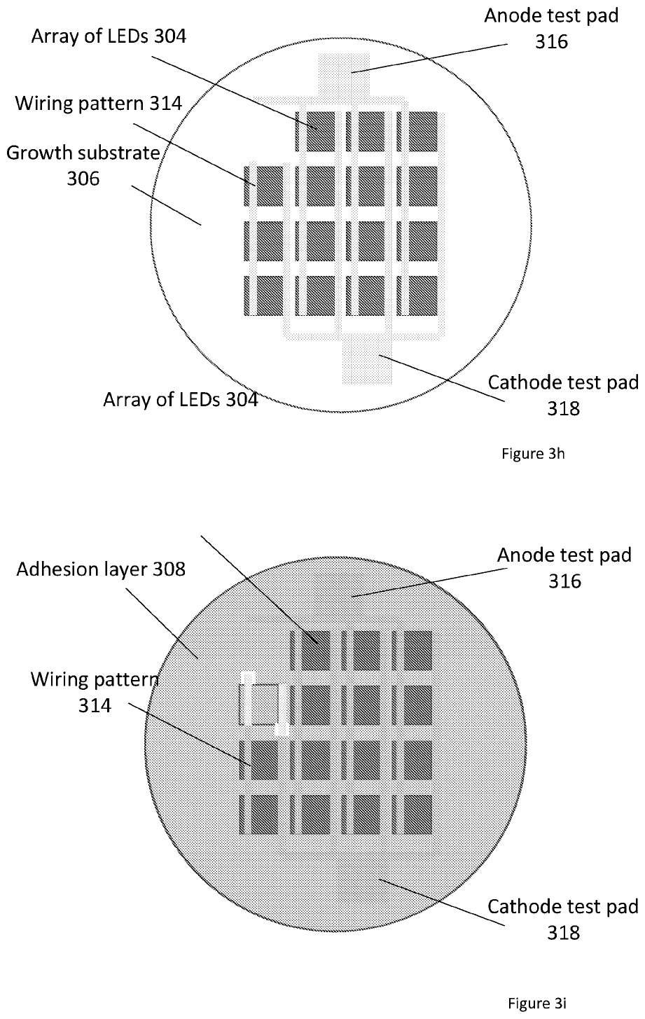

FIG. 1 sets out a method of fabricating a micro-LED display 300. The method of FIG. 1 can be performed by a system for fabricating a micro-LED display. FIGS. 3a to 3i illustrate a schematic diagram of the method of fabricating a micro-LED display. While FIGS. 3a to 3i only depict an array with 16 LEDs, it will be appreciated that any number of LEDs may be present in the array.

In step 102, a micro-LED wafer 302 is provided. The micro-LED wafer 302 may be provided as shown in FIG. 3a. The micro-LED wafer 302 may include an array of LEDs 304 deposited on a growth substrate 306. The array of LEDs 304 may include one or more LEDs. FIG. 3a shows an array of 16 LEDs, but it will be understood by the skilled person that this is for illustration only and that the array may include significantly more LEDs in reality. For example, there may be approximately one million LEDs in the array of LEDs 304. The one or more LEDs in the array of LEDs 304 may be one or more of micro-LEDs, nano-LEDs, quantum dots, organic LEDs, or any other type of LED with any suitable size. The one or more of LEDs may be configured to emit a predetermined colour of light, such as light with a specific wavelength, or light within a specific band of wavelengths. The growth substrate 306 may be a sapphire substrate, or made from other suitable materials such as zinc oxide or silicon carbide. Optionally, a sequence of semiconductor layers may be deposited to form the array of LEDs 304 on the growth substrate 306.

Optionally, in step 104, a wiring pattern 314 is deposited on the micro-LED wafer 302 to connect the array of LEDs 304 to a current source. The wiring pattern 314 may be connect to an anode test pad 316 and a cathode test pad 318, as shown in in FIG. 3b. The anode test pad 316 may comprise gold connected to the Indium Tin Oxide (ITO) layer on the anode of the LEDs and the cathode test pad 318 may comprise gold connected to an n-Gallium Nitride (n-GaN) layer that forms the cathode of the LEDs. The cathode may be common to all LEDs or the devices may be isolated by etching so that the wiring pattern is required to connect the common cathode test pad to the cathode connection. Optionally, in step 106, a current is applied to the wiring pattern 314 to test the LEDs. The current may be of an appropriate amperage so as to illuminate the array of LEDs when it is applied between the anode and cathode. The current may be applied to every LED to illuminate them all to allow for imaging and image processing to determine LEDs. Optionally, in step 108, one or more correctly functioning LEDs are selected as the one or more selected LEDs to be connected to the backplane 310 and removed to the display substrate 312. These one or more correctly functioning LEDs may be connected to the backplane 310 and removed to the display substrate 312 individually or in groups of one or more correctly functioning LEDs. Correctly functioning LEDs may be LEDs which illuminate as expected when a current is applied to the wiring pattern 314 and array of LEDs 304. LEDs are not correctly functioning when they do not illuminate when a current is applied to the wiring pattern 314 and array of LEDs 304. The optional steps of 104, 106, and 108 enable the array of LEDs 304 to be wired up prior to backplane processing. By providing a current to the wiring pattern to test the LEDs, all of the LEDs are lit simultaneously and it is then possible to determine which LEDs are working and which LEDs are not working.

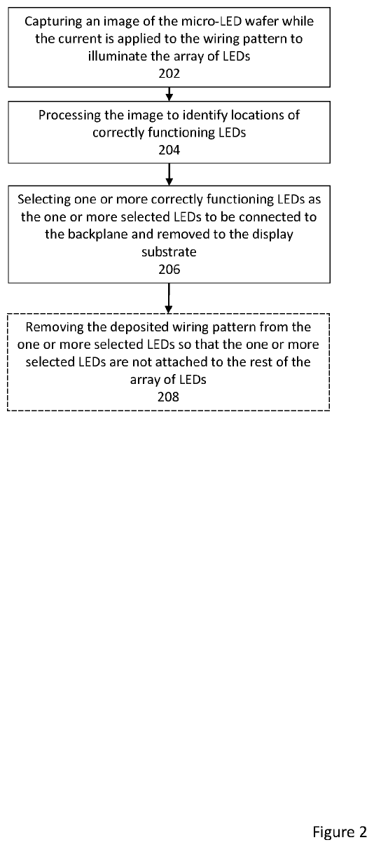

FIG. 2 sets out a method of fabricating a micro-LED display 300, specifically a method for selecting one or more correctly functioning LEDs as the one or more selected LEDs to be connected to the backplane and removed to the display substrate. The method of FIG. 2 can be performed by a system for fabricating a micro-LED display. The step 108 of selecting one or more functioning LEDs may include capturing 202 an image of the micro-LED wafer 302 while the current is applied to the wiring pattern 314 to illuminate the array of LEDs 304. The image of the micro-LED wafer 302 may include the whole array of LEDs 304 or a subsection of the array of LEDs 304. The image of the micro-LED wafer 302 may be stored for future reference and processing. The step 108 may further include processing 204 the image to identify locations of correctly functioning LEDs. Correctly functioning LEDs may be LEDs which illuminate as expected when a current is applied to the wiring pattern 314 and array of LEDs 304. The locations of correctly functioning LEDs may be stored for future reference and for determination of which LEDs are to be selected to be connected to the backplane 310 and removed to the display substrate 312. The step 108 may further include selecting 206 one or more correctly functioning LEDs as the one or more selected LEDs to be connected to the backplane 310 and removed to the display substrate 312. This enables defective LEDs to be avoided, which subsequently means that defective LEDs will not be transferred to a display substrate 312. As such, the number of defective LEDs on the display substrate 312 will be minimised.

The step 108 may further optionally include removing 208 the deposited wiring pattern 314 from the one or more selected LEDs so that the one or more selected LEDs are not attached to the rest of the array of LEDs 304. In step 208, removing the deposited wiring pattern 314 may include wet etching the deposited wiring pattern 314.

In step 110, an adhesion layer 308 is deposited so as to cover the micro-LED wafer 302 while leaving one or more selected LEDs exposed. The adhesion layer 308 may be deposited as shown in FIG. 3c. The one or more selected LEDs may include a sub array of selected LEDs within the array of LEDs 304 on the micro-LED wafer 302. The separation of the selected LEDS in the sub array may correspond to a required pixel separation of the micro-LED display 300. The step 110 of depositing an adhesion layer 308 may include depositing an adhesion layer 308 to cover the micro-LED wafer 302. The step 110 may also include removing one or more sections of the adhesion layer 308 to expose the one or more selected LEDs. Optionally, the adhesion layer 308 may include a photoresist. When the adhesion layer 308 includes a photoresist, one or more sections of the adhesion layer 308 may be exposed to light to expose the one or more selected LEDs. Alternatively, the step of removing one or more sections of the adhesion layer 308 to expose the one or more selected LEDs may include using digital lithography to define the one or more selected LEDs which are exposed. The one or more selected LEDs which are exposed or left exposed may be one or more functioning LEDs. This enables a random distribution of defective LEDs to be avoided, which subsequently means that defective LEDs will not be transferred to a display substrate 312. As such, the number of defective LEDs on the display substrate 312 will be minimised.

Optionally, if not already completed in step 208, the deposited wiring pattern 314 may be removed from the one or more selected LEDs so that the one or more selected LEDs are not attached to the rest of the array of LEDs 304. The deposited wiring pattern 314 may be removed from the one or more selected LEDs so that the one or more selected LEDs as shown in FIG. 3d. Removing the exposed deposited circuitry may include wet etching the exposed deposited circuitry.

In step 112, a backplane 310 is deposited on the adhesion layer 308, such that the backplane 310 is aligned with and operatively connected to the exposed one or more LEDs. The backplane 310 may be deposited on the adhesion layer 308 as shown in FIG. 3e. Alignment of the backplane 310 with the exposed one or more LEDs ensures that the exposed one or more LEDs can be correctly positioned and connected to the backplane 310. Operatively connected to may mean that the backplane and the exposed one or more LEDs are connected by one or more interlayer connects, for example by one or more vias. The backplane 310 may include one or more thin film transistors (TFTs). When the backplane 310 includes one or more TFTs, the step of depositing 112 the backplane 310 on the adhesive layer 308 includes connecting the one or more TFTs to the exposed one or more LEDs. The backplane 310 may be configured as shown in FIG. 5.

In step 114, the deposited backplane 310 and connected one or more LEDs are removed to a display substrate 312. The deposited backplane 310 and connected one or more LEDs may be removed to a display substrate 312 as shown in FIG. 3g. The display substrate 312 may be a laminate plastic substrate. The display substrate 312 may alternatively, or additionally, be a flexible substrate. If the display substrate 312 is a flexible substrate, this enables a flexible device to be produced. The step 114 of removing the deposited backplane 310 and connected one or more LEDs to a display substrate 312 may include attaching the display substrate 312 on the deposited backplane 310, as shown in FIG. 3f. The display substrate 312 may be attached to the deposited backplane by lamination, with the aid of adhesives, or the substrate may be a coated polymer that is cured to form a thick polymer film. The coated polymer may be coated from solution. The step 114 may also include freeing the one or more selected LEDs from the growth substrate 306 of the micro-LED wafer 302. The step of freeing the one or more selected LEDs from the growth substrate 306 may be carried out via any suitable etching technique or achieved by using a laser. For example, freeing the one or more selected LEDs from the growth substrate 306 may be carried out by ablating the one or more LEDs with a laser. The step 114 may also include lifting away the display substrate 312 with the attached backplane 310 and one or more connected LEDs. As the display substrate 312 has been attached to the deposited backplane 310, the backplane 310 has been attached to the one or more selected LEDs, and the one or more selected LEDs have been freed from the growth substrate 306, the step of lifting away may involve pulling the display substrate 312 and growth substrate 306 in opposite directions from each other, in the plane of the growth direction. The step 114 may result in the growth substrate 306 and remaining array of LEDs 304 as shown in FIG. 3h.

Some or all of the deposited adhesion layer 308 may remain attached to the deposited backplane 310 after it has been removed 114 to a display substrate 312. The remaining deposited adhesion layer 308 may be removed from the backplane 310 before it is placed on a display substrate 312. Alternatively, or additionally, some or all of the deposited adhesion layer 308 may remain attached to the micro-LED wafer 302 after the deposited backplane 310 has been removed 114 to the display substrate 312. The remaining deposited adhesion layer may be removed from the micro-LED wafer 302 after the deposited backplane 310 has been removed 114 to the display substrate 312.

In step 116, an adhesion layer 308 is deposited so as to cover the micro-LED wafer 302 while leaving one or more further LEDs exposed. The adhesion layer 308 may be deposited so as to cover the micro-LED wafer 302 while leaving one or more further LEDs exposed, as show in FIG. 3i. The one or more selected LEDs may include a sub array of selected LEDs within the array of LEDs 304 on the micro-LED wafer 302. The separation of the selected LEDS in the sub array may correspond to a required pixel separation of the micro-LED display 300. The step 116 of depositing an adhesion layer 308 may include depositing an adhesion layer 308 to cover the micro-LED wafer 302. The step 116 may also include removing one or more sections of the adhesion layer 308 to expose the one or more selected LEDs. Optionally, the adhesion layer 308 may include a photoresist. When the adhesion layer 308 includes a photoresist, one or more sections of the adhesion layer 308 may be exposed to light to expose the one or more selected LEDs. Alternatively, the step of removing one or more sections of the adhesion layer 308 to expose the one or more selected LEDs may include using digital lithography to define the one or more selected LEDs which are exposed. The one or more selected LEDs which are exposed or left exposed may be one or more functioning LEDs. This enables a random distribution of defective LEDs to be avoided, which subsequently means that defective LEDs will not be transferred to a display substrate 312. As such, the number of defective LEDs on the display substrate 312 will be minimised.

In step 118, the deposited backplane 310 is defined as a first backplane 310 and a second backplane is deposited such that the second backplane is aligned with and operatively connected to the exposed one or more further LEDs. Alignment of the second backplane with the exposed one or more LEDs ensures that the exposed one or more LEDs can be correctly positioned and connected to the backplane 310. Operatively connected to may mean that the backplane and the exposed one or more LEDs are connected by one or more interlayer connects, for example by one or more vias. The second backplane may include one or more thin film transistors (TFTs). When the second backplane includes one or more TFTs, the step of depositing 118 the second backplane on the adhesive layer 308 includes connecting the one or more TFTs to the exposed one or more LEDs. The second backplane may be configured as shown in FIG. 5.

In step 120, the deposited second backplane and connected one or more further LEDs are removed to a display substrate 312. The deposited second backplane and connected one or more further LEDs may be removed to the same display substrate 312 as the first backplane 310. The display substrate 312 may be a laminate plastic substrate. The display substrate 312 may alternatively, or additionally, be a flexible substrate. If the display substrate 312 is a flexible substrate, this enables a flexible device to be produced. The step 120 of removing the deposited second backplane and connected one or more LEDs to a display substrate 312 may include attaching the display substrate 312 on the second deposited backplane. The display substrate 312 may be attached to the deposited backplane by lamination, with the aid of adhesives, or the substrate may be a coated polymer that is cured to form a thick polymer film. The step 120 may also include freeing the one or more selected LEDs from the growth substrate 306 of the micro-LED wafer 302. The step of freeing the one or more selected LEDs from the growth substrate 306 may be carried out via any suitable etching technique or achieved by using a laser. For example, freeing the one or more selected LEDs from the growth substrate 306 may be carried out by ablating the one or more LEDs with a laser. The step 120 may also include lifting away the display substrate 312 with the attached second backplane and one or more connected LEDs. As the display substrate 312 has been attached to the second deposited backplane, the second backplane has been attached to the one or more selected LEDs, and the one or more selected LEDs have been freed from the growth substrate 306, the step of lifting away may involve pulling the display substrate 312 and growth substrate 306 in opposite directions from each other, in the plane of the growth direction. The step 120 may result in the growth substrate 306 and remaining array of LEDs 304 as shown in FIG. 3h.

Some or all of the deposited adhesion layer 308 may remain attached to the second deposited backplane after it has been removed 114 to a display substrate 312. The remaining deposited adhesion layer 308 may be removed from the second backplane before it is placed on a display substrate 312. Alternatively, or additionally, some or all of the deposited adhesion layer 308 may remain attached to the micro-LED wafer 302 after the second deposited backplane has been removed 114 to the display substrate 312. The remaining deposited adhesion layer may be removed from the micro-LED wafer 302 after the second deposited backplane has been removed 114 to the display substrate 312.

This method may be repeated multiple times until no more functioning LEDs remain in the array of LEDs 304 on the growth substrate. In this scenario, the only remaining LEDs may be LEDs which do not function.

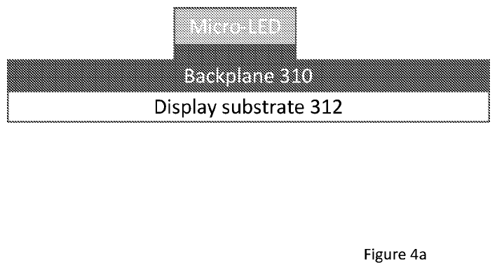

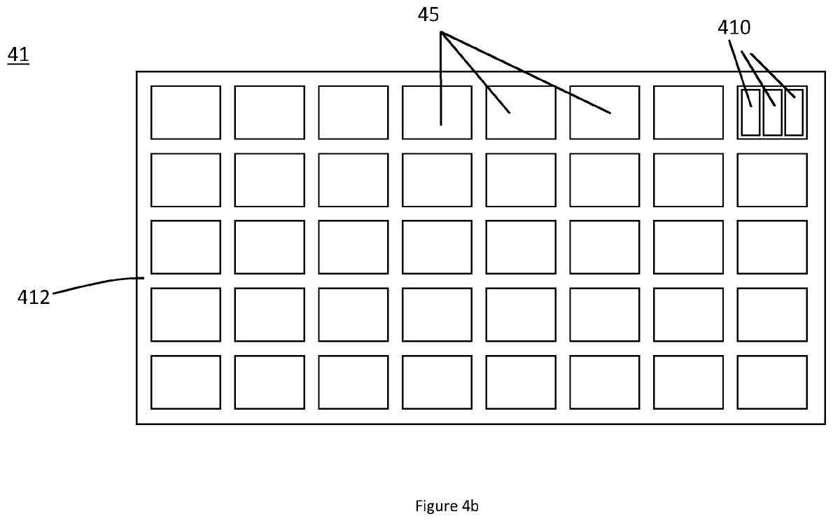

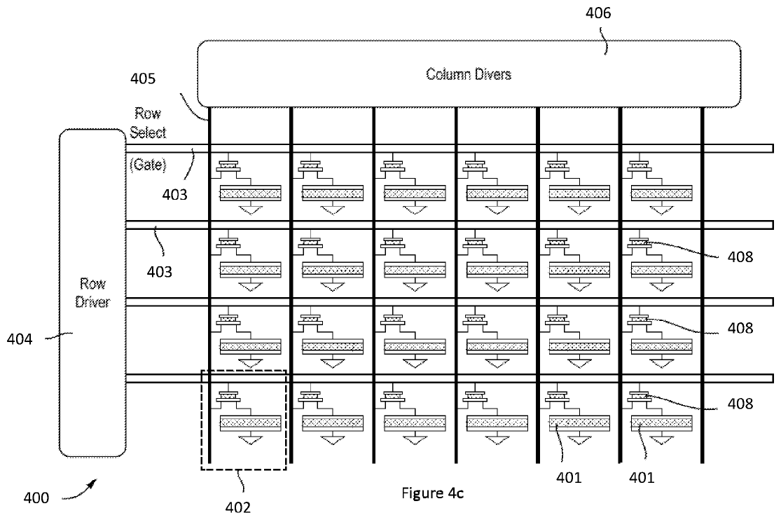

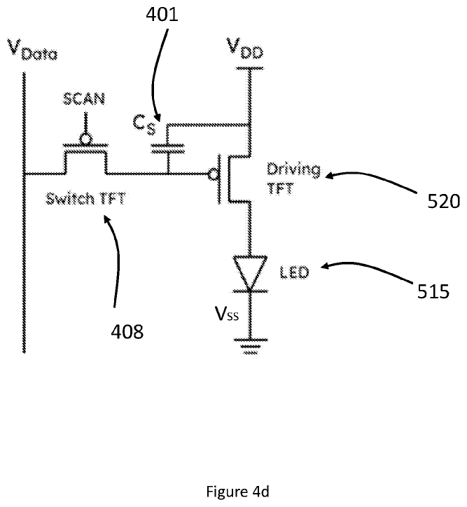

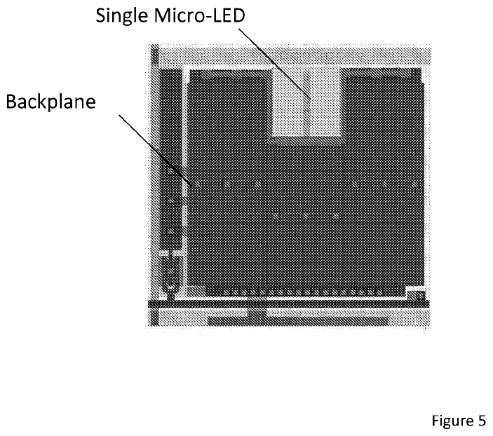

FIG. 4a illustrates a micro-LED display 300. The micro-LED display may include a plurality of LEDs, each having a top surface and an opposing bottom surface. The plurality of LEDs may be one or more of micro-LEDs, nano-LEDs, quantum dots, organic LEDs, or any other type of LED with any suitable size. The plurality of LEDs may be configured to emit a predetermined colour of light, such as light with a specific wavelength, or light within a specific band of wavelengths. The top surface of the LEDs may correspond to a growth direction and the bottom surface of the LEDs may have been removed from a growth substrate 306. While FIG. 4a only depicts an array with one LED, it will be appreciated that any number of LEDs may be present in the array in order to provide a particular resolution. The LEDs may be arranged with a certain LED density and/or pitch, to provide display suitable for a range of devices. For example, a high density of LEDs may be particularly appropriate for the display in a VR or AR headset or smartwatch. The growth substrate 306 may be a sapphire substrate, or made from other suitable materials such as zinc oxide or silicon carbide. The micro-LED display 300 may also include a backplane 310 having a top surface and an opposing bottom surface. The backplane 310 may include one or more thin film transistors (TFTs). The backplane 310 may be formed over the top surface of the LEDs and the bottom surface of the backplane 310 may be deposited directly on and operatively connected to the LEDs. The micro-LED display 300 may also include a display substrate 312 attached to the top surface of the backplane 310. The display substrate 312 may be a laminate plastic substrate applied to the top surface of the backplane 310. The display substrate 312 may alternatively, or additionally, be a flexible substrate.

The micro-LED display 300 may also include a reflective layer formed between a top surface of the one or more LEDs and the backplane 310 (not shown in FIG. 4a). The reflective layer may be arranged to reflect light emitted by the LEDs such that reflected light is emitted from the micro-LED display 300 in a direction corresponding to the bottom surface of the LEDs. The reflective layer preferably covers at least 50% of the areas of the LEDs. The reflective layer may be a metal layer, and may comprise Al, Ag, Mo, and/or Au. Alternatively, the reflective layer may comprise a distributed Bragg reflector, which has polarising properties that may be useful in illuminating liquid crystal displays (LCDs) located beneath the LED display device. When the micro-LED display 300 includes a reflective layer, the display substrate 312 may be at least partially transparent. If the display substrate 312 is partially transparent, it is preferably at least 70% transparent. The display substrate 312 may be polished on the bottom surface, so as not to affect the quality of the image from the micro-LED display 300. Optionally, one or more lenses (not shown) and/or colour filters may be provided on the bottom surface of the display substrate to collimate or focus light or adjust the wavelength of the light exiting the display substrate 312. Optionally, the display substrate 312 may be thinned through backgrinding or chemical etching prior to polishing to reduce the distance between the LED and the optical element.

The embodiment described above provides a number of advantages. Firstly, the use of a reflective layer to direct upwardly emitted light back through the display substrate 312 means the backplane 310 may cover a large area without obscuring each LED. Therefore, in comparison to prior art monolithic devices in which the area of the backplane 310 is restricted, in the present invention the backplane 310 can provide more current for each LED. Secondly, light emitted in a direction opposite to the intended emission direction is no longer wasted, but reflected such that a greater proportion of the light emitted by each LED is emitted in the intended emission direction, thereby producing a more efficient micro-LED display 300. This means that the LEDs may operate at a lower temperature in order to produce the same light output; this reduces the stress on the backplane 310, which may improve the performance and lifetime of the micro-LED display 300.

One issue associated with manufacturing monolithic displays is that the metal used in the reflective layer and the LEDs may be damaged by high temperatures, such as temperatures exceeding 150° C. For inorganic backplanes 310, such as amorphous silicon (a-Si), low-temperature polycrystalline silicon (LTPS), and/or indium gallium zinc oxide (IGZO), the PECVD process is used to deposit dielectric layers of high quality SiNₓ. However, this is only effective at temperatures above 300° C., which would damage the LEDs, and/or the reflective layer that are already present within the micro-LED display.

For this reason, it is particularly advantageous if the backplane 310 is an organic TFT (OTFT). OTFTs may be deposited onto the display 300 at a much lower temperature than used when depositing inorganic TFTs, and thus it is possible to avoid damaging the reflective layer and/or the LEDs. For example, it is possible to process OTFTs at temperatures as low as 80° C. since the heating is only required to remove a coating solvent from formulated ink. The low temperature deposition processes for OTFT ensure that the reflective layer and LED are not damaged and so forming monolithic devices using OTFTs is particularly advantageous.

Suitable structures and materials for the OTFT are described in WO2022/101644 and WO2020/002914. For example, the OTFT may comprise an organic semiconducting (OSC) layer, an organic gate insulator (OGI) layer, a sputter resistance layer (SRL), a substrate, and a base layer. The OSC layer may comprise at least one semiconducting ink including a small molecule organic semiconductor and an organic binder. The OGI layer of the OTFT may comprise a material as described in WO2020/002914. The SRL may comprise a cross-linked organic layer as described in WO2020/002914. The cross-linked organic layer is preferably obtainable by polymerisation of a solution comprising at least one non-fluorinated multi-functional acrylate, a non-acrylate organic solvent, a cross-linkable fluorinated surfactant and a silicone surfactant, where the silicone surfactant is preferably a cross-linkable silicone surfactant and may be a non-fluorinated surfactant. The silicone surfactant may be an acrylate- and/or methacrylate-functionalised silicone surfactant. The substrate may comprise glass or a polymer. The base layer may comprise an organic cross-linked layer, with suitable materials described in WO2020/002914.

The micro-LED display 300 may be combined with other components in order to provide a display device. For example, protective layers, frames, electrical connections, and/or any other suitable components may be combined with the micro-LED display 300. The micro-LED display 300 may be utilised for the display in a VR or AR headset or smartwatch.

Each LED of the micro-LED display 300 is individually addressable, with the state of each LED being controlled by the backplane 310, which may include one or more thin film transistors (TFTs). The TFTs may be used as switching devices for controlling an operation of each LED and/or as driving devices for driving LEDs.

FIG. 4b illustrates a schematic diagram of a display component 41, comprising an array of pixels 45. While FIG. 4b only depicts an array with 40 pixels 45, it will be appreciated that any number of pixels 45 may be present in the array in order to provide a particular resolution. As will be described later in more detail, the pixels 45 may comprise sub-pixels that may be configured to emit light in predetermined colours, for example to provide an RGB display. Additionally, the pixels may be arranged with a certain pixel density and/or pixel pitch, to provide displays suitable for a range of devices. For example, a high density of pixels 45 may be particularly appropriate for the display in a VR or AR headset or smartwatch. Other components may be combined with display component 41 in order to provide a display device. For example, protective layers, frames, electrical connections and/or any other suitable components may be combined with the display component 41.

Each pixel 45 (or sub-pixel) of the display component 41 is individually addressable, with the state of each pixel 45 being controlled by one or more thin film transistors (TFTs). The TFTs are used as switching devices for controlling an operation of each pixel, and/or as driving devices for driving pixels. For example, TFTs may act as switches and current drivers for micro-LED displays, organic LED (OLED) displays, or quantum dot light-emissive diode (QD-LED) displays. Each pixel of the display component 41 is provided by one or more integrated circuits 410 that are provided on a substrate 412. For example, one integrated circuit 410 may provide a pixel 45 of the display component 41, or a plurality of integrated circuits 410 may be used to provide a plurality of sub-pixels of the display component 41. As shown for an exemplary pixel 45 in FIG. 4b, three integrated circuits 410 are provided for each pixel 45. TFTs may also be used to operate LEDs that provide backlight zones of a liquid crystal display (LCD), where each LED provides a backlight for a plurality of LCD pixels. By dividing the backlight into a plurality of backlight zones each controlled by a separate TFT, it is possible to improve the energy efficiency and contrast ratio of the LCD, since zones may be fully turned off when not required. For example, one TFT may be used to switch the LED backlight for a zone of about one hundred LCD pixels. Therefore, the term “integrated circuit 410” as used herein may refer to an individual pixel 45 of the display, and may also refer to a backlight zone provided by an LED, where each backlight zone corresponds to a plurality of LCD pixels.

The display component 41 in FIG. 4b is a monolithic display component 41, where the integrated circuits 410 are deposited (or “grown”) on a substrate 412, rather than being transferred to the substrate 412 from a separate (“source wafer”). In this way, the substrate 412 of the display component 41 may also be referred to as the source wafer. In a monolithic display, the integrated circuits 410 may be produced by forming a number of layers on top of the substrate 412. This may be achieved using a chemical vapour deposition (CVD) technique such as plasma-enhanced chemical vapour deposition (PECVD) or metalorganic chemical vapour deposition (MOCVD), or an epitaxy technique such as metalorganic vapour-phase epitaxy (MOVPE), or molecular beam epitaxy (MBE). These techniques allow thin films (or “layers”) of material to be deposited on the substrate 412 in order to form each of the integrated circuits 410. Subsequently, portions of the layers may be selectively removed in a process known as patterning, which may be achieved by (dry) etching. In this way, it is possible to electrically isolate adjacent integrated circuits from each other, and form channels for electrical pathways through the layers.

The process for individually addressing pixels 5 will now be described in more detail with reference to FIGS. 4c and 4d. FIG. 4c illustrates a transistor array 400 for a backplane of a display, where the transistor array 400 comprises a plurality of integrated circuits 402 arranged in a regular array of rows and columns. Each integrated circuit 402 includes a thin film transistor (TFT) 408. As in a conventional active matrix display, each TFT acts as a switch for controlling the application of current to a corresponding pixel capacitor 401, where each integrated circuit 402 may comprise a 2T-1C or other combination of transistors and capacitors.

The backplane comprises a series of row (scan or gate) lines 403 connected to the gate of each TFT 408 in a common row, where each row line 403 is connected to a row driver 404 for applying a voltage to the gate of each of the TFTs in a particular row. The source or drain terminal of each TFT 408 in a particular column is connected to a column (or data) line 405. A row driver 406 is connected to each gate line 405 and a column driver 406 is connected to each data line 405. Each integrated circuit 402 is individually addressable by providing a voltage pulse with the row driver 404 to turn on each TFT 408 in a row while providing the required data voltage to the source or drain terminal of each TFT 408. By scanning through each row in sequence and applying the data voltages to each data line 405, a data signal can be written into the pixel capacitors 401 of the matrix. In this way, the transistor and capacitor of each integrated circuit 402 may maintain the state of a pixel while other pixels are being addressed.

FIG. 4d depicts an example of a 2T-1C integrated circuit 402 comprising a select or switch TFT 408, a driving TFT 520 as well as a storage capacitor 401. When the row (scan) line is turned on, the data signal, V_{Data}, can write a voltage onto the storage capacitor 401 that is also connected to the gate of the driving TFT 520. If the V_{DD} and V_{SS} voltages are applied then the change in resistance of the driving TFT 520 will cause a current to flow through the LED 515 in relation to the voltage applied to the gate of the driving TFT 520, thus modulating the amount of light emitted from the display.

FIG. 5 illustrates a single pixel design which forms a section of a backplane utilized in the above-described method. The backplane is formed of repeat units of this pixel according to the numbers of rows and columns required in the backplane array matrix.

FIG. 3b illustrates an integrated circuit for testing LEDs for a micro-LED display 300. The integrated circuit may include a micro-LED wafer 302. The micro-LED wafer 302 may include an array of LEDs 304 deposited on a growth substrate 306. The growth substrate 306 may be a sapphire substrate, or made from other suitable materials such as zinc oxide or silicon carbide. The integrated circuit may also include a wiring pattern 314 deposited on the micro-LED wafer 302. The wiring pattern 314 may be connect to an anode test pad 316 and a cathode test pad 318, as shown in in FIG. 3b. The anode test pad 316 may comprise gold connected to the Indium Tin Oxide (ITO) layer on the anode of the LEDs and the cathode test pad 318 may comprise gold connected to an n-Gallium Nitride (n-GaN) layer that forms the cathode of the LEDs. The cathode may be common to all LEDs or the devices may be isolated by etching so that the wiring pattern is required to connect the common cathode test pad to the cathode connection The wiring pattern 314 may connect each of the LEDs of the array of LEDs to a current source to test the LEDs prior to transfer to a micro-LED display, as set out in FIG. 2. The current may be of an appropriate amperage so as to illuminate the array of LEDs when it is applied between the anode and cathode. The integrated circuit may be configured such that current may be applied to every LED to illuminate them all to allow for imaging and image processing to determine which LEDs are functional and which LEDs are not functional.

While the foregoing is directed to exemplary embodiments of the present invention, it will be understood that the present invention is described herein purely by way of example, and modifications of detail can be made within the scope of the invention. Furthermore, one skilled in the art will understand that the present invention may not be limited by the embodiments disclosed herein, or to any details shown in the accompanying figures that are not described in detail herein or defined in the claims. Indeed, such superfluous features may be removed from the figures without prejudice to the present invention.

Moreover, other and further embodiments of the invention will be apparent to those skilled in the art from consideration of the specification, and may be devised without departing from the basic scope thereof, which is determined by the claims that follow.

1. A method of fabricating a micro-LED display (300), the method comprising:
providing (102) a micro-LED wafer (302) comprising an array of LEDs (304) deposited on a growth substrate (306);
depositing (110) an adhesion layer (308) so as to cover the micro-LED wafer (302) while leaving one or more selected LEDs exposed;
depositing (112) a backplane (310) on the adhesion layer (308), such that the backplane (310) is aligned with and operatively connected to the exposed one or more LEDs; and
removing (114) the deposited backplane (310) and connected one or more LEDs to a display substrate (312).

2. The method of claim 1, wherein the step of depositing (110) an adhesion layer (308) comprises:
depositing an adhesion layer (308) to cover the micro-LED wafer (302); and
removing one or more sections of the adhesion layer (308) to expose the one or more selected LEDs.

3. The method of claim 2, wherein the adhesion layer (308) comprises a photoresist, the method comprising:
exposing the one or more sections of the adhesion layer (308) to light to expose the one or more selected LEDs.

4. The method of claim 1, wherein the step of providing (102) a micro-LED wafer (302) comprises:
depositing a sequence of semiconductor layers to form the array of LEDs (304) on the growth substrate (306).

5. The method of claim 1 wherein, prior to depositing (110) the adhesion layer (308), the method comprises:
depositing (104) a wiring pattern (314) on the micro-LED wafer to connect the array of LEDs (304) to a current source;
applying (106) a current to the wiring pattern (314) to test the LEDs; and
selecting (108) one or more correctly functioning LEDs as the one or more selected LEDs to be connected to the backplane (310) and removed to the display substrate (312).

6. The method of claim 5 wherein the step of selecting (108) one or more functioning LEDs comprises:
capturing an image of the micro-LED wafer while the current is applied to the wiring pattern to illuminate the array of LEDs;
processing the image to identify locations of correctly functioning LEDs; and
selecting one or more correctly functioning LEDs as the one or more selected LEDs to be connected to the backplane and removed to the display substrate.

7. The method of claim 5, wherein the method comprises:
removing (208) the deposited wiring pattern (314) from the one or more selected LEDs so that the one or more selected LEDs are not attached to the rest of the array of LEDs (304).

8. The method of claim 7, wherein removing (208) the exposed deposited circuitry comprises wet etching the exposed deposited circuitry.

9. The method of claim 1, further comprising:
removing the deposited adhesion layer (308) from the backplane (310).

10. The method of claim 1, wherein the removing (114) the deposited backplane (310) and connected one or more LEDs to a display substrate (312) comprises:
attaching the display substrate (312) on the deposited backplane (310);
freeing the one or more selected LEDs from the growth substrate (306) of the micro-LED wafer (302); and
lifting away the display substrate (312) with the attached backplane (310) and one or more connected LEDs.

11. The method of claim 10, wherein freeing the one or more selected LEDs from the growth substrate (306) comprises ablating the one or more LEDs with a laser.

12. The method of claim 1, wherein the display substrate (312) comprises a laminate plastic substrate.

13. The method of claim 1, wherein the display substrate (312) comprises a polymer coated from solution and cured to form a thick polymer film.

14. The method of claim 1, wherein the display substrate (312) is a flexible substrate.

15. The method of claim 1, wherein the backplane (310) comprises one or more thin film transistors, TFTs, where the step of depositing (112) the backplane (310) on the adhesive layer comprises connecting the one or more TFTs to the exposed one or more LEDs.

16. The method of claim 1, wherein the one or more selected LEDs comprise a sub array of selected LEDs within the array of LEDs (304) on the micro-LED wafer (302) with the separation of the selected LEDs in the sub array corresponding to a required pixel separation of the micro-LED display (300).

17. The method of claim 1, wherein after removing (114) the deposited backplane (310) and the one or more connected LEDs to a display substrate (312), where the deposited backplane (310) is defined as a first backplane (310), the method further comprises:
depositing (116) an adhesion layer (308) so as to cover the micro-LED wafer (302) while leaving one or more further LEDs exposed;
depositing (118) a second backplane such that the second backplane is aligned with and operatively connected to the exposed one or more further LEDs; and
removing (120) the deposited second backplane and connected one or more further LEDs to a display substrate (312).

18. The method of claim 17, wherein the deposited second backplane and connected one or more further LEDs are removed (120) to the same display substrate (312) as the first backplane (310).

19. The method of claim 1, wherein the LEDs comprise one or more of micro-LEDs, nano-LEDs, quantum dots.

20. The method of claim 1, wherein the growth substrate (306) is a sapphire substrate.

21. The method of claim 2, wherein removing one or more sections of the adhesion layer (308) to expose the one or more selected LEDs comprises:
using digital lithography to define the one or more selected LEDs which are exposed.

22. A micro-LED display (300) comprising:
a plurality of LEDs, each having a top surface and an opposing bottom surface;
a backplane (310) having a top surface and an opposing bottom surface, the backplane (310) formed over the top surface of the LEDs, wherein the bottom surface of the backplane (310) is deposited directly on and operatively connected to the LEDs; and
a display substrate (312) attached to the top surface of the backplane (310).

23. The micro-LED display of claim 22, wherein the top surface of the LEDs corresponds to the growth direction, where the bottom surface has been removed from a growth substrate (306).

24. The micro-LED display of claim 22, wherein the display substrate (312) comprises a laminate plastic substrate applied to the top surface of the backplane (310).

25. The micro-LED display of claim 22 further comprising a reflective layer formed between a top surface of the one or more LEDs and the backplane (310), the reflective layer arranged to reflect light emitted by the LEDs such that reflected light is emitted from the micro-LED display (300) in a direction corresponding to the bottom surface of the LEDs.

26. An integrated circuit for testing LEDs for a micro-LED display (300), the integrated circuit comprising:
a micro-LED wafer (302) comprising an array of LEDs (304) deposited on a growth substrate (306); and
a wiring pattern (314) deposited on the micro-LED wafer (302) to connect each of the LEDs of the array of LEDs to a current source to test the LEDs prior to transfer to a micro-LED display (300).
